(19) United States
(12) Patent Application Publication
(10) Pub. No.: US 2022/0165765 A1
(43) Pub. Date: May 26, 2022

(54) IMAGE SENSOR AND IMAGE SENSING SYSTEM

(71) Applicant: SAMSUNG ELECTRONICS CO., LTD., Suwon-si (KR)

(72) Inventors: Tae Sub JUNG, Hwaseong-si (KR); Seung Ki BAEK, Suwon-si (KR); Kyung Ho LEE, Suwon-si (KR)

(21) Appl. No.: 17/373,924

(22) Filed: Jul. 13, 2021

(30) Foreign Application Priority Data
Nov. 26, 2020 (KR) 10-2020-0160706

(51) Int. Cl. H01L 27/146; H04N 9/04

(52) U.S. Cl. CPC H01L 27/14605; H04N 9/04555; H01L 27/14621; H01L 27/1463

(57) ABSTRACT

An image sensor includes a first element separation film inside a substrate and having a mesh shape, pixel regions on the substrate defined by the first element separation film and including at least first and second pixel regions, and a second element separation film inside the substrate and partitioning the first pixel region into sub-pixel regions, the second element separation film not being in the second pixel region, wherein the first pixel region includes first photoelectric conversion elements, and a first color filter on the first photoelectric conversion elements, the first color filter being one of white, green, and blue color filters, and wherein the second pixel region includes second photoelectric conversion elements, and a second color filter on the second photoelectric conversion elements, the second color filter being different from the first color filter and one of red and white color filters.

### CROSS-REFERENCE TO RELATED APPLICATION

Korean Patent Application No. 10-2020-0160706 filed on Nov. 26, 2020, in the Korean Intellectual Property Office, and entitled: “Image Sensor and Image Sensing System,” is incorporated by reference herein in its entirety.

### BACKGROUND

### 1. Field

The present disclosure relates to an image sensor and an image sensing system.

### 2. Description of the Related Art

An image sensing device is one of semiconductor elements that convert optical information into electric signals. Such an image sensing device may include a charge coupled device (CCD) image sensing device and a complementary metal-oxide semiconductor (CMOS) image sensing device.

The CMOS image sensor may be abbreviated as a CIS (CMOS image sensor). The CIS may be equipped with a plurality of pixels arranged two-dimensionally. Each of the pixels may include, e.g., a photo diode. The photo diode may convert incident light into electrical signals.

Recently, with the development of the computer industry and the telecommunications industry, there are increasing demands for image sensors with improved performance in various fields, e.g., a digital camera, a video camera, a smart phone, a game console, a security camera, a medical micro camera, a robot, etc.

### SUMMARY

According to an embodiment of the present disclosure, the image sensor includes a first element separation film placed inside a substrate in a form of a mesh, a plurality of pixel regions defined by the first element separation film, and including a first pixel region and a second pixel region, and a second element separation film which is disposed inside the substrate and partitions the first pixel region into a plurality of sub-pixel regions, wherein the first pixel region includes a plurality of first photoelectric conversion elements, and a first color filter on the plurality of first photoelectric conversion elements, the second pixel region includes a plurality of second photoelectric conversion elements, and a second color filter on the plurality of second photoelectric conversion elements, the second color filter is different from the first color filter, the first color filter is one of a white color filter, a green color filter, and a blue color filter, the second color filter is one of a red color filter and a white color filter, and the second element separation film is not placed inside the substrate of the second pixel region.

According to the aforementioned and other embodiments of the present disclosure, an image sensor includes a substrate including a first pixel region and a second pixel region, a plurality of first photoelectric conversion elements formed inside the substrate in the first pixel region, a plurality of second photoelectric conversion elements formed inside the substrate in the second pixel region, a boundary separation film which defines a boundary between the first and second pixel regions, a pattern film formed inside the substrate of the first pixel region, a first color filter which is formed on the first pixel region of the substrate, and a second color filter which is formed on the second pixel region of the substrate and different from the first color filter, wherein the first color filter is one of a white color filter, a green color filter, and a blue color filter, the second color filter is a red color filter, and the pattern film is not placed inside the substrate of the second pixel region.

According to the aforementioned and other embodiments of the present disclosure, the image sensing system includes an image sensor which outputs an image signal, and an image signal processor which is connected to the image sensor and receives and processes the image signal, wherein the image sensor includes a substrate, a first element separation film placed inside the substrate in a form of a mesh, a plurality of pixel regions defined by the first element separation film, and including a first pixel region, a second pixel region, and a third pixel region, a second element separation film which is disposed inside the substrate and partitions the first pixel region into a plurality of sub-pixel regions, and a third element separation film which is disposed inside the substrate and partitions the third pixel region into a plurality of sub-pixel regions, the second pixel region is in contact with the first pixel region with the first element separation film as a boundary, and is in contact with the third pixel region with the first element separation film as a boundary, the first pixel region includes a plurality of first photoelectric conversion elements, and a first color filter on the plurality of first photoelectric conversion elements, the second pixel region includes a plurality of second photoelectric conversion elements, and a second color filter on the plurality of second photoelectric conversion elements, the third pixel region includes a plurality of third photoelectric conversion elements, and a third color filter on the plurality of third photoelectric conversion elements, the second color filter is different from the first and third color filters, the first color filter is one of a white color filter, a green color filter, and a blue color filter, the second color filter is one of a red color filter and a white color filter, the third color filter is one of the white color filter, the green color filter, and the blue color filter, and the second and third element separation films are not placed inside the substrate of the second pixel region.

### BRIEF DESCRIPTION OF THE DRAWINGS

Features will become apparent to those of skill in the art by describing in detail exemplary embodiments with reference to the attached drawings, in which:

FIG. 1 is a block diagram of an image sensing system according to some embodiments.

FIG. 2 is a conceptual diagram of a layout of the image sensor of FIG. 1.

FIG. 3 is a diagram of a pixel array according to some embodiments.

FIG. 4 is a diagram of a pixel array in region RG1 of FIG. 3.

FIGS. 5 and 6 are cross-sectional views along line A-A of FIG. 4.

FIG. 7 is a diagram of a pixel array of region RG2 of FIG. 4.

FIGS. 8 to 10 are diagrams of a crosstalk imbalance due to the pixels of the pixel array.

FIGS. 11A to 11E are diagrams of pixel arrays according to some embodiments.

FIGS. 12A to 12F are diagrams of a pixel array according to some embodiments.

FIGS. 13A to 13D are diagrams of a pixel array according to some embodiments.

FIG. 14 is a diagram of a plurality of pixels and signal lines of an image sensor according to some embodiments.

FIG. 15 is an equivalent circuit diagram of two pixels of an image sensor according to some embodiments.

FIG. 16 is a block diagram of an electronic device including a multi-camera module according to some embodiments.

### DETAILED DESCRIPTION

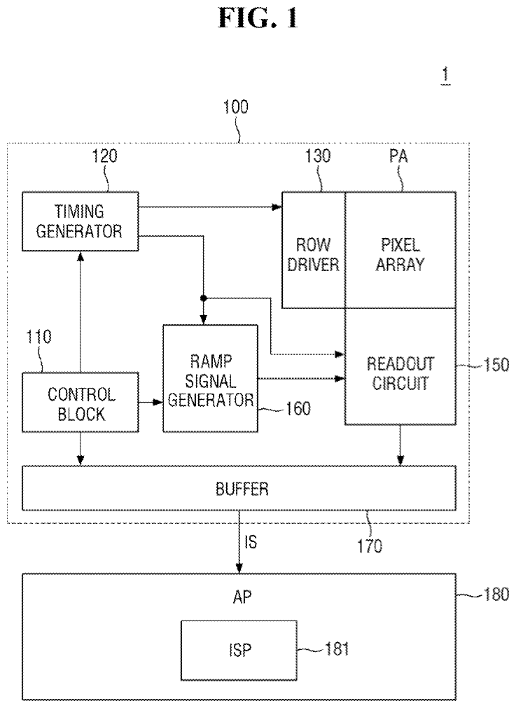

An image sensing system 1 including an image sensor 100 with a pixel array PA will be described below referring to FIGS. 1 to 16.

FIG. 1 is a block diagram of an image sensing system according to some embodiments.

Referring to FIG. 1, the image sensing system 1 may include the image sensor 100 and an application processor 180. For example, the image sensor 100 may be placed in a camera module or any other suitable module.

The image sensor 100 may generate an image signal IS by sensing an image to be sensed, using incident light. In some embodiments, although the generated image signal IS may be, e.g., a digital signal, the embodiments are not limited thereto.

The image signal IS may be provided to the application processor 180 and processed. That is, the image signal IS may be provided to an image signal processor (ISP) 181 included in the application processor 180 and processed. The ISP 181 may process or treat the image signal IS to be easily displayed.

In some embodiments, the image sensor 100 and the application processor 180 may be placed separately as shown. For example, the image sensor 100 may be mounted on a first chip, the application processor 180 may be mounted on a second chip, and they may communicate with each other through an interface. However, example embodiments are not limited thereto, e.g., the image sensor 100 and the application processor 180 may be implemented as a single package (e.g., a multi-chip package (MCP)).

The image sensor 100 may include a control register block 110, a timing generator 120, a row driver 130, the pixel array PA, a readout circuit 150, a ramp signal generator 160, and a buffer 170.

The control register block 110 may generally control the operation of the image sensor 100. In particular, the control register block 110 may directly transmit an operating signal to the timing generator 120, the ramp signal generator 160, and the buffer 170.

The timing generator 120 may generate a signal that serves as a reference for the operation timing of various components of the image sensor 100. The operation timing reference signal generated by the timing generator 120 may be transferred to the row driver 130, the readout circuit 150, the ramp signal generator 160, and the like.

The ramp signal generator 160 may generate and transmit the ramp signal to be used in the readout circuit 150. For example, the readout circuit 150 may include a correlated double sampler (CDS), a comparator, and the like. The ramp signal generator 160 may generate and transmit the ramp signal to be used in the CDS, the comparator, or the like.

The buffer 170 may include, e.g., a latch. The buffer 170 may temporarily store the image signal IS to be provided to the outside, and may transmit the image signal IS to an external memory or an external device.

The pixel array PAs may sense external images. The pixel array PA may include a plurality of pixels (or unit pixels). The row driver 130 may selectively activate the row of the pixel array PA.

The readout circuit 150 may sample the pixel signal provided from the pixel array PA, compare the pixel signal with the ramp signal, and then, convert an analog image signal (data) into a digital image signal (data) on the basis of the results of the comparison.

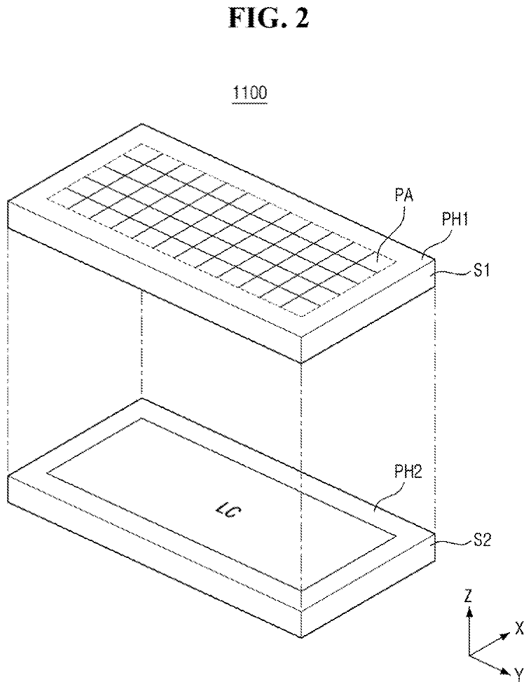

FIG. 2 is a conceptual diagram of a layout of the image sensor 100 in FIG. 1.

Referring to FIG. 2, the image sensor 100 may include a first region S1 and a second region S2 stacked in a third direction (e.g., a vertical direction along the Z-axis). The first region S1 and the second region S2 may extend in first and second directions (e.g., horizontal directions along the X-axis and the Y-axis) intersecting the third direction, as shown, and blocks shown in FIG. 1 may be placed in the first region S1 and the second region S2.

Although not shown in the drawing, a third region in which the memory is placed may be placed below the second region S2. At this time, the memory placed in the third region may receive the image data from the first region S1 and the second region S2, store or process the image data, and transmit the image data to the first region S1 and the second region S2 again. In this case, the memory may include a memory element, e.g., a dynamic random access memory (DRAM) element, a static random access memory (SRAM) element, a spin transfer torque magnetic random access memory (STT-MRAM) element, and a flash memory element. When the memory includes, e.g., the DRAM element, the memory may receive the image data at a relatively high speed and process the image data. Also, in some embodiments, the memory may also be placed in the second region S2.

The first region S1 may include the pixel array PA and a first peripheral region PH1, and the second region S2 may include a logic circuit region LC and a second peripheral region PH2. The first region S1 and the second region S2 may be sequentially stacked and placed one above the other.

In the first region S1, the pixel array PA may be the same as the pixel array PA described referring to FIG. 1. The pixel array PA may include a plurality of unit pixels arranged in a matrix form. Each pixel may include a photo diode and transistors. A more specific description thereof will be provided below.

The first peripheral region PH1 may include a plurality of pads, and may be placed around the pixel array PA. The plurality of pads may transmit and receive electrical signals from an external device or the like.

In the second region S2, the logic circuit region LC may include electronic elements including a plurality of transistors. The electronic elements included in the logic circuit region LC are electrically connected to the pixel array PA to provide a constant signal to each unit pixel of the pixel array PA or control the output signal.

For example, the control register block 110, the timing generator 120, the row driver 130, the readout circuit 150, the ramp signal generator 160, the buffer 170, and the like described referring to FIG. 1 may be placed in the logic circuit region LC. For example, blocks other than the pixel array PA among the blocks of FIG. 1 may be placed in the logic circuit region LC.

Although a second peripheral region PH2 may also be placed in a region of the second region S2, which corresponds to the first peripheral region PH1 of the first region S1, the embodiments are not limited thereto.

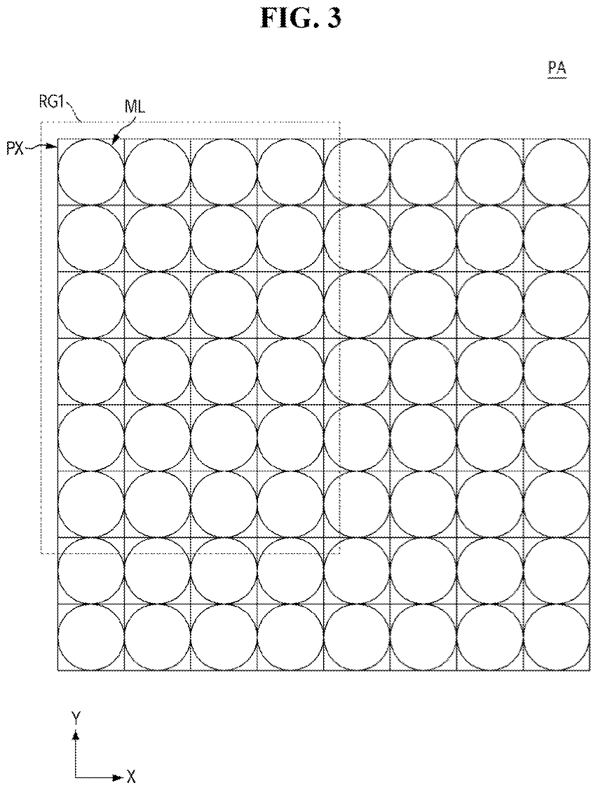

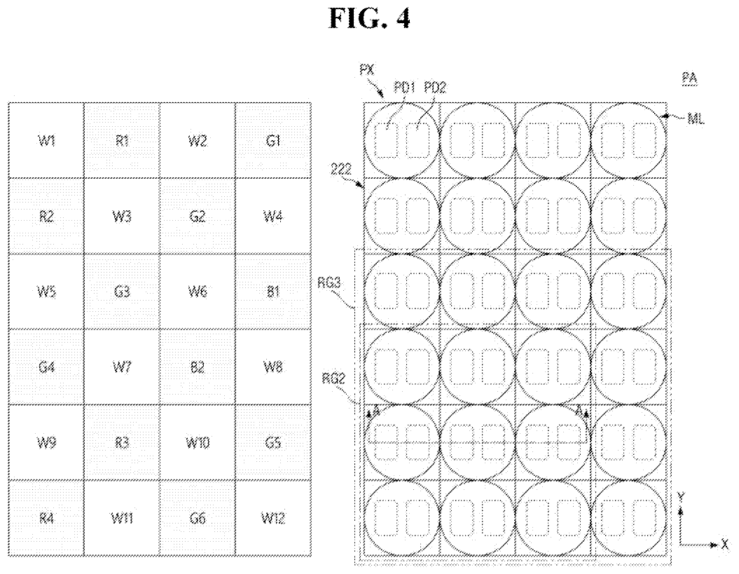

FIG. 3 is a diagram of the pixel array PA according to some embodiments. FIG. 4 is an enlarged diagram of a portion of the pixel array PA in region RG1 of FIG. 3.

Referring to FIG. 3, the pixel array PA may include a plurality of pixel regions PX. The plurality of pixel regions PX may be arranged two-dimensionally. For example, the plurality of pixel regions PX may be repeatedly placed in the first direction and the second direction, e.g., along the X and Y axes. The pixel regions PX may be arranged at regular intervals. However, example embodiments according are not limited thereto, e.g., the pixel regions PX may also be arranged in other forms.

Each pixel region PX may include a micro lens ML. Each micro lens ML may be placed above each pixel region PX. That is, when viewed from above, the micro lens ML may be placed on an upper surface of the pixel array PA. Each micro lens ML may correspond to each pixel region PX, e.g., in a one-to-one correspondence.

Referring to FIG. 4, the portion of the pixel array PA in the region RG1 may include a plurality of pixel regions. For example, the pixel array PA of the region RG1 may include first to twelfth white pixel regions W1 to W12, first to sixth green pixel regions G1 to G6, first to fourth red pixel regions R1 to R4, first and second blue pixel regions B1 and B2, and the like.

Although two pixel arrays PA are shown in FIG. 4, this is for convenience of explanation only, and the left and right pixel arrays PA in FIG. 4 are the same array, with each pixel region in the left pixel array PA corresponding to a respective pixel region in the right pixel array PA. That is, the left pixel array PA shows the type of pixel region, while the right pixel array PA shows the form and configuration of the pixel array PA. For convenience of explanation, this will be expressed in the same manner in the following drawings.

In the pixel array PA, each of the first to twelfth white pixel regions W1 to W12 may be surrounded by each of the first to sixth green pixel regions G1 to G6, the first to fourth red pixel regions R1 to R4, and the first and second blue pixel regions B1 and B2. In addition, in the pixel array PA, the first to sixth green pixel regions G1 to G6, the first to fourth red pixel regions R1 to R4, and the first and second blue pixel regions B1 and B2 may be surrounded by each of first to twelfth white pixel regions W1 to W12. That is, each pixel region may be defined in a mesh-shaped pixel array PA.

For example, the third white pixel region W3 may be surrounded by first and second red pixel regions R1 and R2, and second and third green pixel regions G2 and G3. That is, the third white pixel region W3 may share a boundary with the first and second red pixel regions R1 and R2, and the second and third green pixel regions G2 and G3. Also, for example, the third green pixel region G3 may be surrounded by the third, fifth, sixth and seventh white pixel regions W3, W5, W6 and W7. That is, the third green pixel region G3 may share the boundary with the third, fifth, sixth and seventh white pixel regions W3, W5, W6 and W7.

Each pixel region may be defined by a first element separation film 222. The first element separation film 222 may be placed in the form of a mesh, e.g., the solid grid lines in FIG. 4. For example, the first element separation film 222 may be placed in the form of a mesh along the first direction X and the second direction Y. The respective first element separation films 222 may intersect each other. The mesh-shaped first element separation film 222 may define each pixel region PX in the pixel array PA, e.g., each square of the solid grid lines in FIG. 4 may completely surround each micro lens ML (corresponding to a pixel region PX). For example, the first element separation film 222 may define the first to twelfth white pixel regions W1 to W12, the first to sixth green pixel regions G1 to G6, the first to fourth red pixel regions R1 to R4, and the second blue pixel regions B1 and B2.

Each pixel region PX may include a plurality of photoelectric conversion elements. For example, each pixel region PX may include a first photoelectric conversion element PD1 and a second photoelectric conversion element PD2. The first and second photoelectric conversion elements PD1 and PD2 may be placed side by side in the first direction X within each of the pixel region PX. However, example embodiments are not limited thereto, e.g., the pixel region PX may include only one photoelectric conversion element or may include four photoelectric conversion elements.

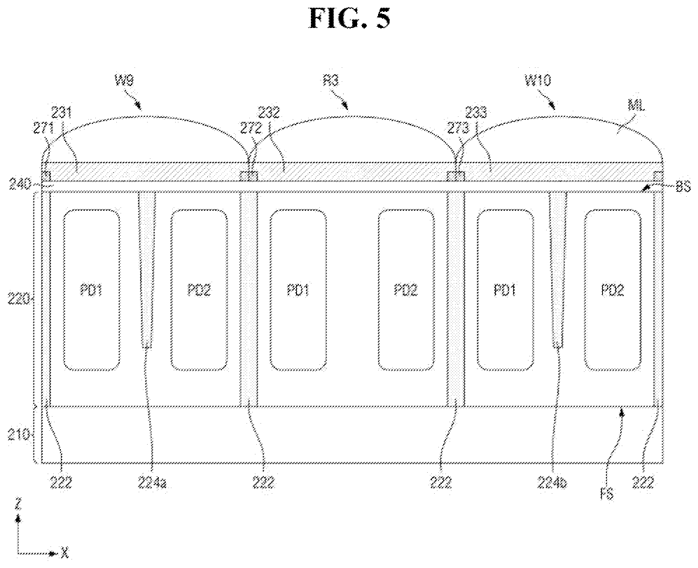

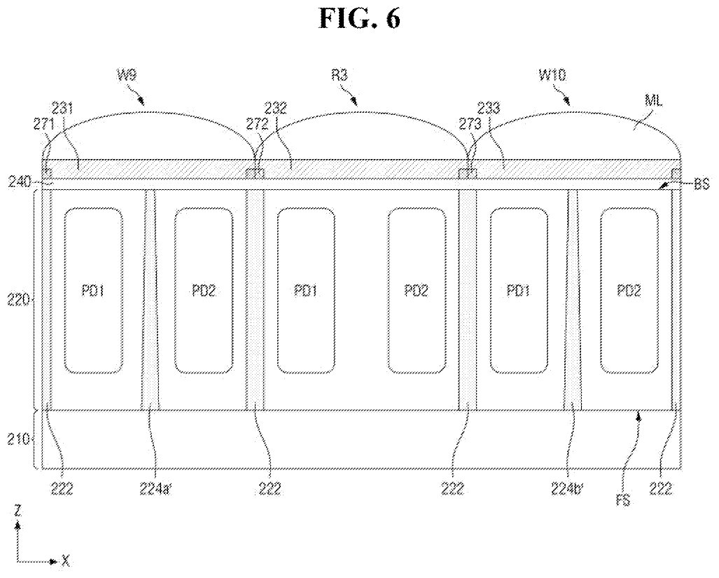

FIGS. 5 and 6 are cross-sectional views of the pixel array PA along line A-A of FIG. 4.

Referring to FIG. 5, the pixel array PA may include a ninth white pixel region W9, a third red pixel region R3, and a tenth white pixel region W10. In the pixel array PA, the ninth white pixel region W9, the third red pixel region R3, and the tenth white pixel region W10 may be arranged side by side along the first direction X. That is, the third red pixel region R3 may be placed between the ninth white pixel region W9 and the tenth white pixel region W10.

The pixel array PA according to some embodiments may include a semiconductor substrate 220 having a first surface BS and a second surface FS opposite to each other. For example, the semiconductor substrate 220 may include silicon, germanium, silicon-germanium, a group VI compound semiconductor, a group V compound semiconductor, and the like. The semiconductor substrate 220 may be a silicon substrate into which P-type or N-type impurities are injected. Hereinafter, an example in which P-type impurities are injected into the semiconductor substrate 220 will be described. Also, the semiconductor substrate 220 may include a floating diffusion node region doped with N-type impurities.

The pixel region PX may include a plurality of photoelectric conversion elements PD1 and PD2, color filters 231, 232 and 233, antireflection films 271, 272 and 273, and the like.

The plurality of photoelectric conversion elements PD1 and PD2 may be placed in, e.g., inside, the semiconductor substrate 220. For example, the plurality of photoelectric conversion elements PD1 and PD2 may not be exposed to the first surface BS and second surface FS of the semiconductor substrate 220, e.g., the photoelectric conversion elements PD1 and PD2 may be vertically spaced apart from each of the first and second surface BS and FS of the semiconductor substrate 220. Each of the photoelectric conversion elements PD1 and PD2 may be formed by a PN junction. The photoelectric conversion elements PD1 and PD2 may include impurities having a conductivity type opposite to that of the semiconductor substrate 220. For example, the photoelectric conversion elements PD1 and PD2 may be formed by ion-implantation of N-type impurities into the semiconductor substrate 220. The photoelectric conversion elements PD1 and PD2 may be formed in a form in which a plurality of doping regions are stacked.

The mesh-shaped first element separation film 222 may be formed in the semiconductor substrate 220. The first element separation film 222 may be formed to penetrate, e.g., an entire thickness of, the semiconductor substrate 220. That is, the first element separation film 222 may be exposed to, e.g., in direct contact with, the first surface BS and the second surface FS. However, example embodiments are not limited thereto, e.g., the first element separation film 222 may be exposed only to the first surface BS and may not be exposed to the second surface FS.

A second element separation film 224a may be formed in, e.g., completely within, the semiconductor substrate 220. In the ninth white pixel region W9, the second element separation film 224a may be placed between the first photoelectric conversion element PD1 and the second photoelectric conversion element PD2. Therefore, the first and second photoelectric conversion elements PD1 and PD2 within the ninth white pixel region W9 may be divided, e.g., separated, by the second element separation film 224a. The second element separation film 224a may be formed to extend in the third direction Z. When viewed in a cross-sectional view along the first direction X through the pixel region PX, as illustrated in FIG. 5, the second element separation film 224a may be spaced apart from the first element separation film 222 in the first direction X. However, when viewed in a top view, the second element separation film 224a may be, e.g., directly, connected to the first element separation film 222, e.g., the second element separation film 224a may extend along an entire length of a pixel region PX in the second direction Y to contact opposite horizontal portions of the first element separation film 222 in FIG. 4.

The second element separation film 224b may be formed in, e.g., completely within, the semiconductor substrate 220. In the tenth white pixel region W10, the second element separation film 224b may be placed between the first photoelectric conversion element PD1 and the second photoelectric conversion element PD2. Accordingly, the first and second photoelectric conversion elements PD1 and PD2 may be divided, e.g., separated, by the second element separation film 224b. The second element separation film 224b may be formed to extend in the third direction Z. As discussed previously with reference to the second element separation film 224a, the second element separation film 224b may be spaced apart from the first element separation film 222 in the first direction X in the center of the pixel region PX (as viewed in a cross-sectional view), and may be connected to the first element separation film 222 at the periphery of the pixel region PX (as viewed in a top view).

The second element separation films 224a and 224b may be formed by patterning the semiconductor substrate 220 on the first surface BS side to form a trench, and then burying an insulating material inside the trench. The second element separation films 224a and 224b may be exposed to, e.g., in direct contact with, the first surface BS, but may not be exposed to the second surface FS, e.g., the second element separation films 224a and 224b may be spaced apart from the second surface FS.

The first element separation film 222 and the second element separation films 224a and 224b may include an insulating material, e.g., an oxide, a nitride, and/or polysilicon. In another embodiment, the first element separation film 222 and the second element separation films 224a and 224b may be doped with impurities having a conductivity type opposite to those of the first and second photoelectric conversion elements PD1 and PD2. For example, the first element separation film 222 and the second element separation films 224a and 224b may be formed by ion-implantation of P-type impurities into the semiconductor substrate 220. The impurity concentration of the first element separation film 222 and the second element separation films 224a and 224b may be higher than the impurity concentration of the surrounding semiconductor substrate 220.

The first element separation film 222 may prevent a charge transfer between adjacent pixel regions PX to prevent an electrical crosstalk between the adjacent pixel regions PX. In addition, the first element separation film 222 may refract light obliquely incident on the pixel region PX to prevent an optical crosstalk that may occur when light penetrates the adjacent pixel region PX.

The second element separation films 224a and 224b may prevent a charge transfer between adjacent photoelectric conversion elements PD1 and PD2 within a same pixel region PX to prevent an electrical crosstalk between the adjacent photoelectric conversion elements PD1 and PD2. The second element separation films 224a and 224b may refract light obliquely incident on one of the photoelectric conversion elements PD1 and PD2 to prevent an optical crosstalk that may occur when light penetrates one of the adjacent photoelectric conversion elements PD1 and PD2.

The second element separation films 224a and 224b are placed in the ninth and tenth white pixel regions W9 and W10, while the second element separation film between the photoelectric conversion elements PD1 and PD2 may not be formed in the third red pixel region R3. That is, only a part of the semiconductor substrate 220 may be placed between the photoelectric conversion elements PD1 and PD2 of the third red pixel region R3, e.g., the photoelectric conversion elements PD1 and PD2 in the third red pixel region R3 may be separated only by a portion of the semiconductor substrate 220 without a second element separation film. This will be described later.

Color filters 231, 232 and 233, and the micro lens ML may be placed on the first surface BS of the semiconductor substrate 220. A white color filter 231 and the micro lens ML may be placed on the first surface BS in the ninth white pixel region W9. A red color filter 232 and the micro lens ML may be placed on the first surface BS in the third red pixel region R3. A white color filter 233 and the micro lens ML may be placed on the first surface BS in the tenth white pixel region W10.

The color filters 231, 232 and 233 may select and transmit light of different colors. For example, the white color filters 231 and 233 are transparent and may transmit light of all wavelengths. The red color filter 232 may transmit light red color. Although not shown, a blue color filter may transmit blue color light, and a green color filter may transmit green color light. That is, the length of the wavelength of the light transmitted through the red color filter 232 may be greater than the length of the wavelength of the light transmitted through other color filters.

Antireflection films 271, 272 and 273 may be formed on an insulating layer 240. The antireflection films 271, 272 and 273 may vertically overlap the first element separation film 222. For example, the antireflection film 271 may be placed at the edge of the ninth white pixel region W9. For example, the antireflection film 272 may be placed at the edge of the third red pixel region R3. For example, the antireflection film 273 may be placed at the edge of the tenth white pixel region W10. The thickness of the antireflection films 271, 272 and 273 may be smaller than the thickness of the color filters 231, 232 and 233, e.g., along the third direction Z. Photons reflected or scattered at an interface between the color filters 231, 232 and 233 and the insulating layer 240 may be prevented from moving to other sensing regions.

The antireflection films 271, 272 and 273 may prevent the incident light passing through the color filters 231, 232 and 233 from being reflected or scattered to the side surface. The antireflection films 271, 272 and 273 may include metals, e.g., at least one of tungsten (W), aluminum (Al), and copper (Cu).

The wiring layer 210 may be placed on the second surface FS of the semiconductor substrate 220. The wiring layer 210 may include a plurality of transistors including a pixel region PX, and a plurality of wires connected to the transistors. The wiring layer 210 is electrically connected to the first and second photoelectric conversion elements PD1 and PD2 and may receive analog signals.

The insulating layer 240 may be placed between the first surface BS of the semiconductor substrate 220 and the color filters 231, 232 and 233. The insulating layer 240 may prevent the incident light from being reflected and efficiently transmits the incident light, thereby improving the performance of the image sensor 100.

Referring to FIG. 6, second element separation films 224a′ and 224b′ may be formed by patterning the semiconductor substrate 220 on the second surface FS side to form a trench, and then burying the insulating material in the trench. The second element separation films 224a′ and 224b′ may be exposed to both the first surface BS and the second surface FS. Unlike the second element separation films 224a and 224b, the second element separation films 224a′ and 224b′ may be formed to penetrate the semiconductor substrate 220.

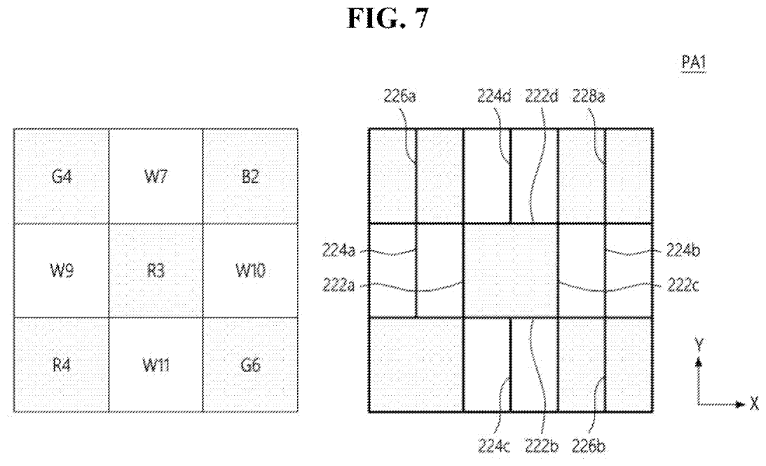

FIG. 7 is a diagram for explaining a pixel array of a region RG2 of FIG. 4.

Referring to FIG. 7, in the pixel array PA1, a fourth green pixel region G4, a seventh white pixel region W7, a second blue pixel region B2, a ninth white pixel region W9, a tenth white pixel region W10, a fourth red pixel region R4, an eleventh white pixel region W11, and a sixth green pixel region G6 may be placed to surround the third red pixel region R3. Each pixel region may be defined by the first element separation film 222.

Here, the third red pixel region R3 may be defined by the first element separation film 222a, the first element separation film 222b, the first element separation film 222c, and the first element separation film 222d. That is, the third red pixel region R3 may be surrounded by the first element separation film 222a, the first element separation film 222b, the first element separation film 222c, and the first element separation film 222d.

The ninth white pixel region W9 may be in contact with, e.g., immediately adjacent to, the third red pixel region R3 with the first element separation film 222a as a boundary therebetween. The eleventh white pixel region W11 may be in contact with, e.g., immediately adjacent to, the third red pixel region R3 with the first element separation film 222b as a boundary therebetween. The tenth white pixel region W10 may be in contact with, e.g., immediately adjacent to, the third red pixel region R3 with the first element separation film 222c as a boundary therebetween. The seventh white pixel region W7 may be in contact with, e.g., immediately adjacent to, the third red pixel region R3 with the first element separation film 222d as a boundary therebetween.

The second element separation film 224a may partition the ninth white pixel region W9 into two sub-pixel regions. The second element separation film 224b may partition the tenth white pixel region W10 into two sub-pixel regions. The second element separation film 224c may partition the eleventh white pixel region W11 into two sub-pixel regions. The second element separation film 224d may partition the seventh white pixel region W7 into two sub-pixel regions. However, example embodiments are not limited thereto, e.g., the second element separation films 224a, 224b, 224c and 224d may be placed in each pixel region and may not necessarily be partitioned. For example, the second element separation films 224a, 224b, 224c and 224d may be pattern films.

The second element separation films 224a, 224b, 224c and 224d may extend in the second direction Y. However, example embodiments are not limited thereto, e.g., the second element separation films 224a, 224b, 224c and 224d may extend in the first direction X, and may also extend in a diagonal direction between the first direction X and the second direction Y.

A third element separation film 226a may partition the fourth green pixel region G4 into two sub-pixel regions. The third element separation film 226b may partition the sixth green pixel region G6 into two sub-pixel regions. The third element separation films 226a and 226b may extend in the second direction Y. However, example embodiments are not limited thereto, e.g., the third element separation films 226a and 226b may extend in the first direction X, and may also extend in a diagonal direction between the first direction X and the second direction Y.

The fourth element separation film 228a may partition the second blue pixel region B2 into two sub-pixel regions. The fourth element separation film 228a may extend in the second direction Y. However, example embodiments are not limited thereto, e.g., the fourth element separation film 228a may extend in the first direction X, and may also extend in a diagonal direction between the first direction X and the second direction Y.

The element separation film that partitions each pixel region into two sub-pixel regions may not be placed in the third red pixel region R3 and the fourth red pixel region R4. That is, element separation films such as the second element separation films 224a, 224b, 224c and 224d, the third element separation films 226a and 226b, the third element separation films 226a and 226b, and the fourth element separation film 228a may not be placed in the third red pixel region R3 and the fourth red pixel region R4.

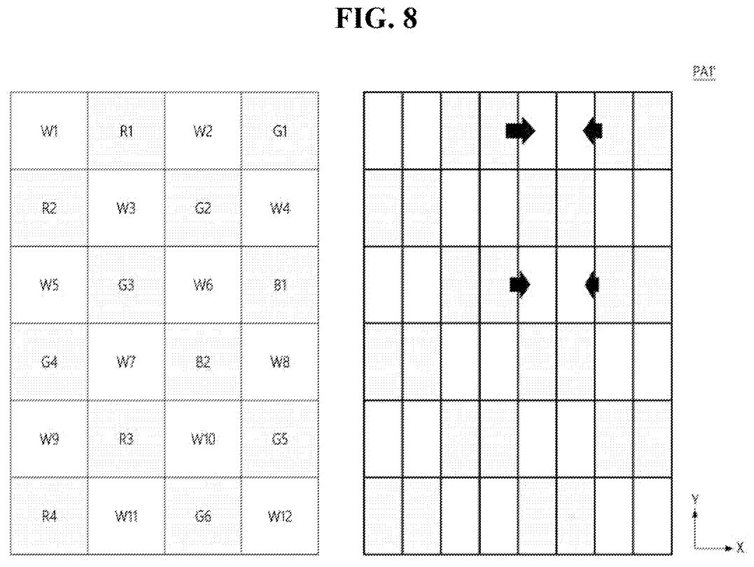

FIGS. 8 to 10 are diagrams for explaining a crosstalk imbalance due to the pixels of the pixel array.

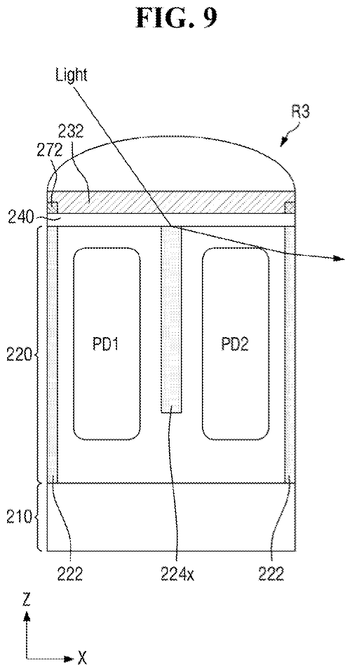

For example, referring to FIG. 8, if a pixel array PA1′ were to include element separation films in each of the pixel regions PX to partition each of the pixel regions PX into sub-pixel regions, including film 224x in the red pixel region R1 to R4 (FIG. 9), light incident on the pixel array PA1′ would have reached the element separation film 224x. For example, light incident on the third red pixel region R3 would have reached the element separation film 224x to be refracted by the element separation film 224x, and to be transferred to other adjacent pixel regions. That is, an optical crosstalk would have occurred by the element separation film 224x. In this case, as the wavelength length of the light incident through the color filters 231, 232 and 233 is large, the optical crosstalk due to the element separation film 224x would have increased.

Referring to FIG. 8, when the light transmitted through the red color filter 232 of the first red pixel region R1 is refracted by the element separation film 224x, a crosstalk of the adjacent second white pixel region W2 may occur. In addition, when the light transmitted through the green color filter of the first green pixel region G1 is refracted by the third element separation film 226a, a crosstalk of the adjacent second white pixel region W2 may occur. When the light transmitted through the green color filter of the third green pixel region G3 is refracted by the third element separation film 226a, a crosstalk of the adjacent sixth white pixel region W6 may occur. When the light transmitted through the blue color filter of the first blue pixel region B1 is refracted by the third element separation film 226b, a crosstalk of the adjacent sixth white pixel region W6 may occur.

Here, since red light having a long wavelength has better refraction than blue light having a short wavelength, the crosstalk occurring in the first red pixel region R1 may be greater than the crosstalk occurring in first green pixel region G1, the third green pixel region G3, and the first blue pixel region B1. As a result, the crosstalk occurring in the second white pixel region W2 may be greater than the crosstalk occurring in the sixth white pixel region W6. That is, since the crosstalk occurring in the second white pixel region W2 and the sixth white pixel region W6 corresponding to the same white channel are different, there may be a problem of a difference in sensitivity.

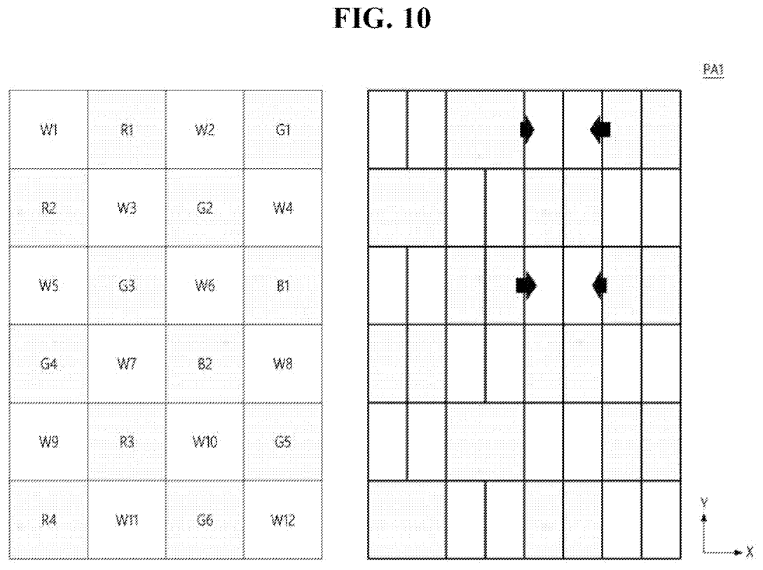

In contrast, as shown in FIG. 10, when the element separation film 224x is not placed in the first to fourth red pixel regions R1 to R4, according to example embodiments, the light transmitted through the red color filter 232 of the first to fourth red pixel regions R1 to R4 may be incident on the first and second photoelectric conversion elements PD1 and PD2. That is, the occurrence of optical crosstalk in other adjacent pixel regions PX may be reduced as compared to a case where the element separation film 224x is placed.

As a result, there may be no difference between the optical crosstalk on the second white pixel region W2 and the optical crosstalk on the sixth white pixel region W6. That is, the optical crosstalk on the second white pixel region W2 and the optical crosstalk on the sixth white pixel region W6 may be substantially the same. As a result, the difference in sensitivity between the second white pixel region W2 and the sixth white pixel region W6 may not occur. As a result, the image quality of the image signal IS that is output from the pixel array PA1 can be further improved.

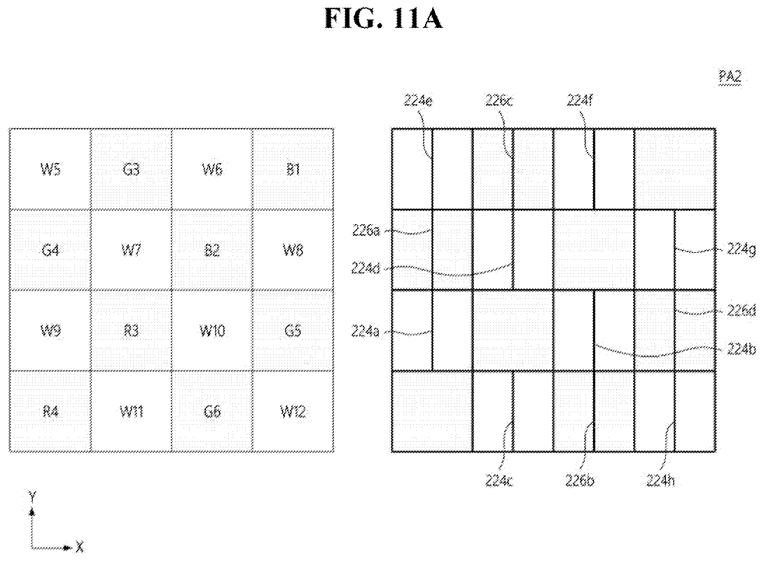

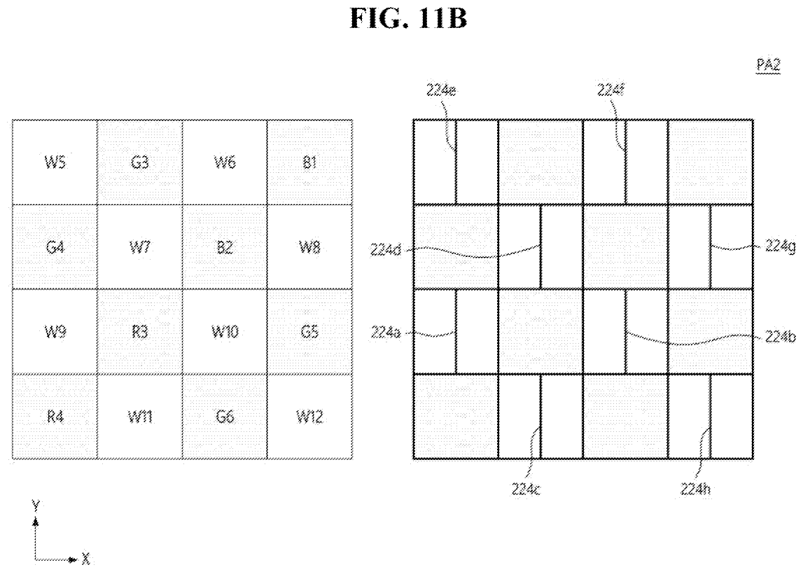

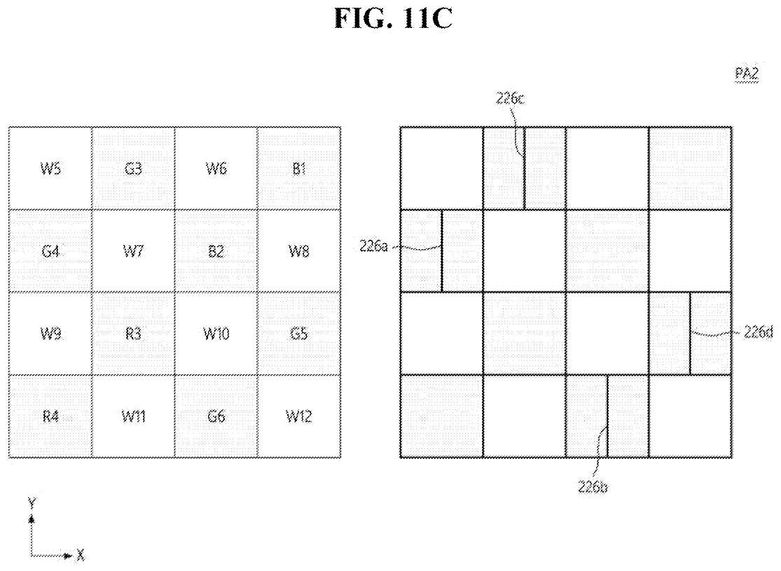

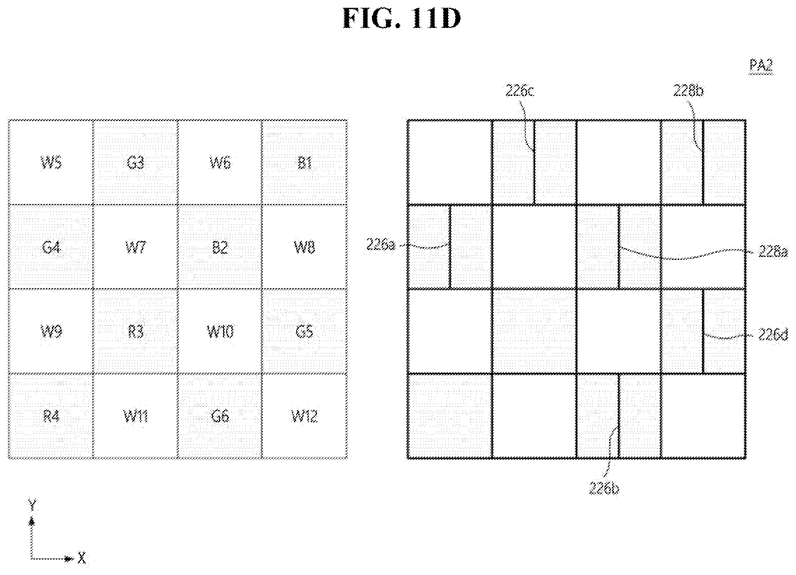

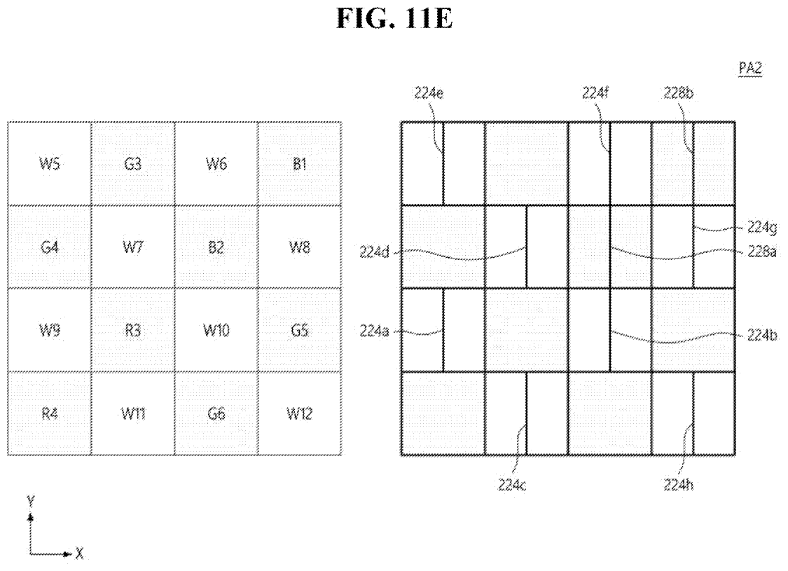

A pixel array PA2 according to some other embodiments will be described below referring to FIGS. 11A to 11E. FIGS. 11A to 11E are diagrams of pixel arrays according to some embodiments. For convenience of explanation, repeated parts of contents explained using FIGS. 1 to 10 will be only briefly explained or omitted.

Referring to FIG. 11A, the pixel array PA2 may be a part of the pixel array PA that corresponds to the region RG3. Hereinafter, the pixel array PA2 corresponding to the region RG3 will be described as an example.

Second element separation films 224a to 224h may be placed in fifth to twelfth white pixel regions W5 to W12. Each of the second element separation films 224a to 224h may partition each of the fifth to twelfth white pixel regions W5 to W12. Third element separation films 226a to 226d may be placed in the third to sixth green pixel regions G3 to G6. Each of the third element separation films 226a to 226d may partition each of the third to sixth green pixel regions G3 to G6.

The element separation film that partitions each pixel region into two sub-pixel regions may not be placed in the third and fourth red pixel regions R3 and R4.

Also, the element separation film that partitions each pixel region into two sub-regions may not be placed in the first and second blue pixel regions B1 and B2. That is, the fourth element separation film 228a may not be placed in the first and second blue pixel regions B1 and B2. Since the fourth element separation film 228a is not placed in the first and second blue pixel regions B1 and B2, the image quality of the image signal IS of the image sensor 100 can be improved.

Referring to FIG. 11B, the second element separation films 224a to 224h may be placed in the fifth to twelfth white pixel regions W5 to W12. Each of the second element separation films 224a to 224h may partition each of the fifth to twelfth white pixel regions W5 to W12.

The element separation film that partitions each pixel region into two sub-pixel regions may not be placed in the third and fourth red pixel regions R3 and R4.

Also, the element separation film that partitions each pixel region into two sub-regions may not be placed in the first and second blue pixel regions B1 and B2. That is, the fourth element separation film 228a may not be placed in the first and second blue pixel regions B1 and B2.

Also, the element separation film that partitions each pixel region into two sub-regions may not be placed in the third to sixth green pixel regions G3 to G6. That is, the third element separation films 226a, 226b, 226c and 226d may not be placed in the third to sixth green pixel regions G3 to G6. Since the third element separation films 226a, 226b, 226c and 226d are not placed in the third to sixth green pixel regions G3 to G6, the image quality of the image signal IS of the image sensor 100 can be improved.

Referring to FIG. 11C, the third element separation films 226a, 226b, 226c and 226d may be placed in the third to sixth green pixel regions G3 to G6.

The second element separation films 224a to 224h may not be placed in the fifth to twelfth white pixel regions W5 to W12. White color filters 231 and 233 of the fifth to twelfth white pixel regions W5 to W12 may transmit lights of all colors. That is, since the fifth to twelfth white pixel regions W12 to W5 may transmit light of long wavelength, the crosstalk of the adjacent pixel region PX may be increased. Since the second element separation films 224a to 224h are not placed in the fifth to twelfth white pixel regions W5 to W12, the image quality of the image signal IS of the image sensor 100 can be improved.

Referring to FIG. 11D, the third element separation films 226a, 226b, 226c and 226d may be placed in the third to sixth green pixel regions G3 to G6. Further, the fourth element separation films 228a and 228b may be placed in the first and second blue pixel regions B1 and B2.

The second element separation films 224a to 224h may not be placed in the fifth to twelfth white pixel regions W5 to W12. Also, element separation films may not be placed in the third and fourth red pixel regions R3 and R4. Since the element separation film is not placed in the fifth to twelfth white pixel regions W5 to W12 and the third and fourth red pixel regions R3 and R4 that transmit light of long wavelength, the image quality of the image signal IS of the image sensor 100 can be improved.

Referring to FIG. 11E, the second element separation films 224a to 224h may be placed in the fifth to twelfth white pixel regions W5 to W12. Further, the fourth element separation films 228a and 228b may be placed in the first and second blue pixel regions B1 and B2. Since the element separation film is not placed in the third and fourth red pixel regions R3 and R4 that transmit light of long wavelength, the image quality of the image signal IS of the image sensor 100 can be improved.

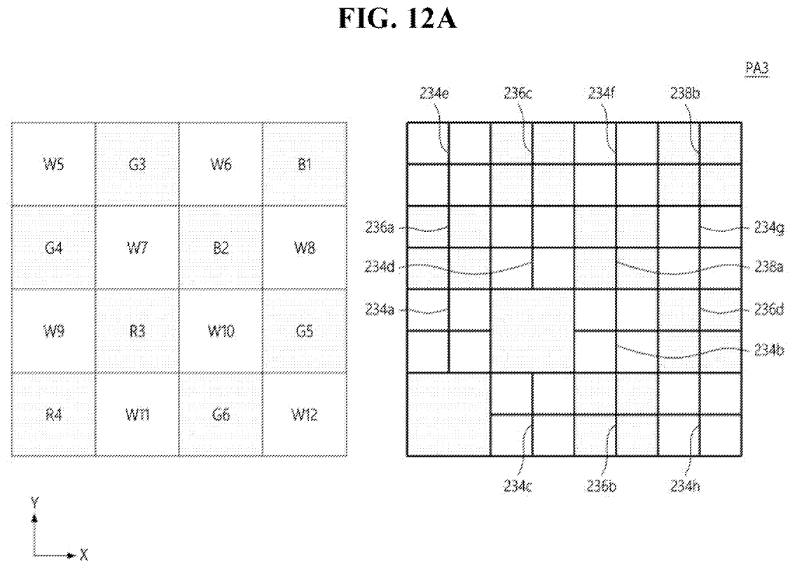

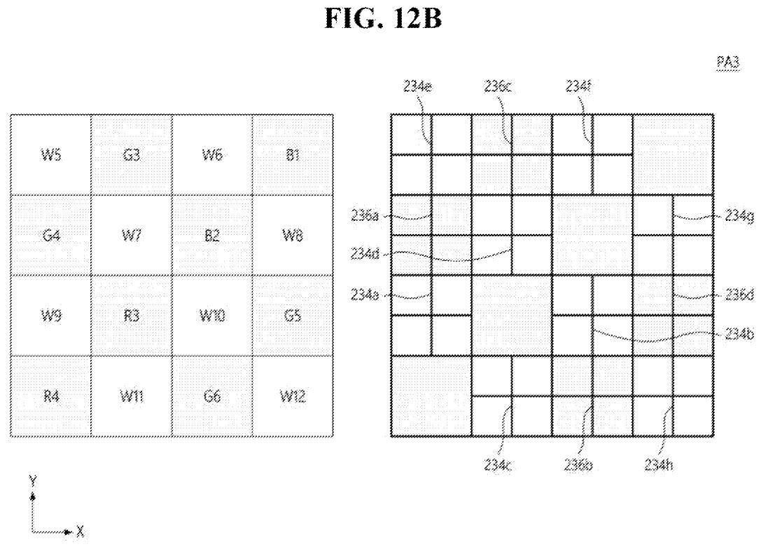

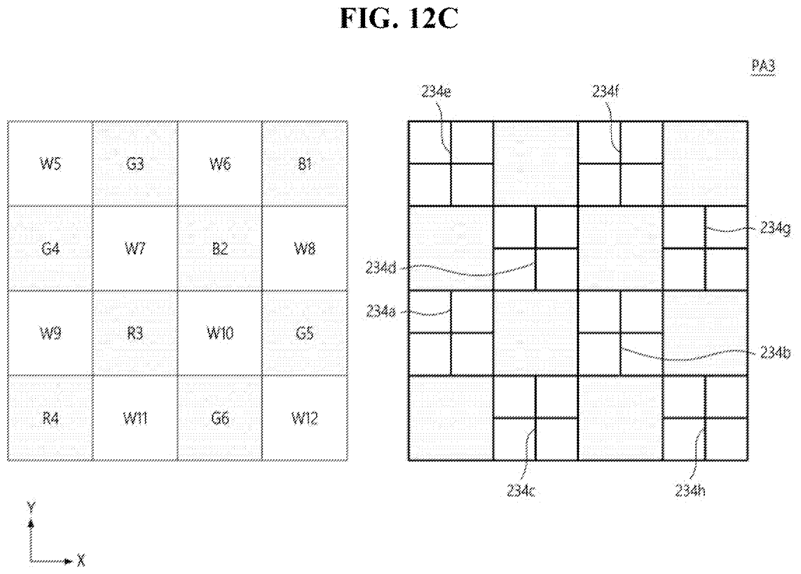

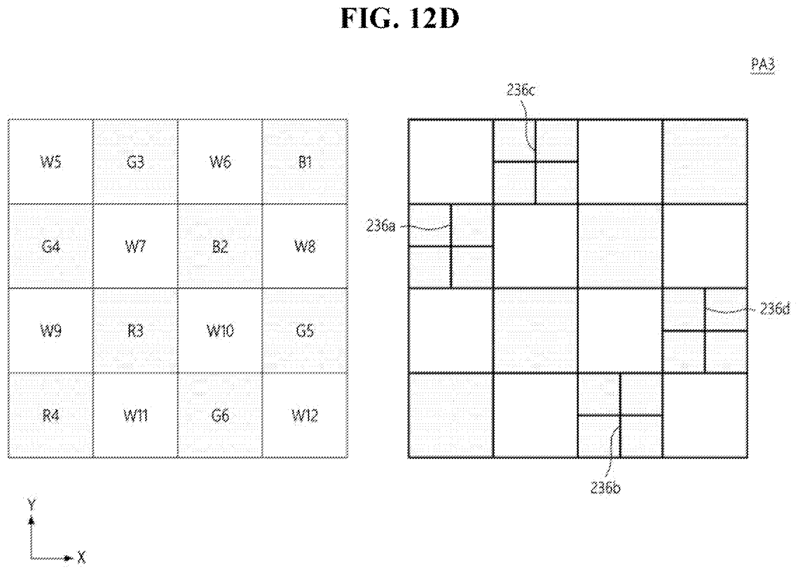

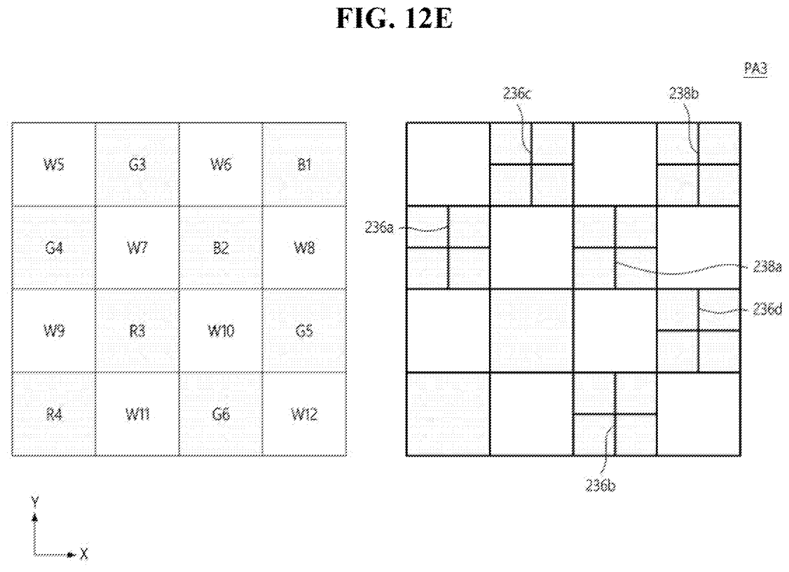

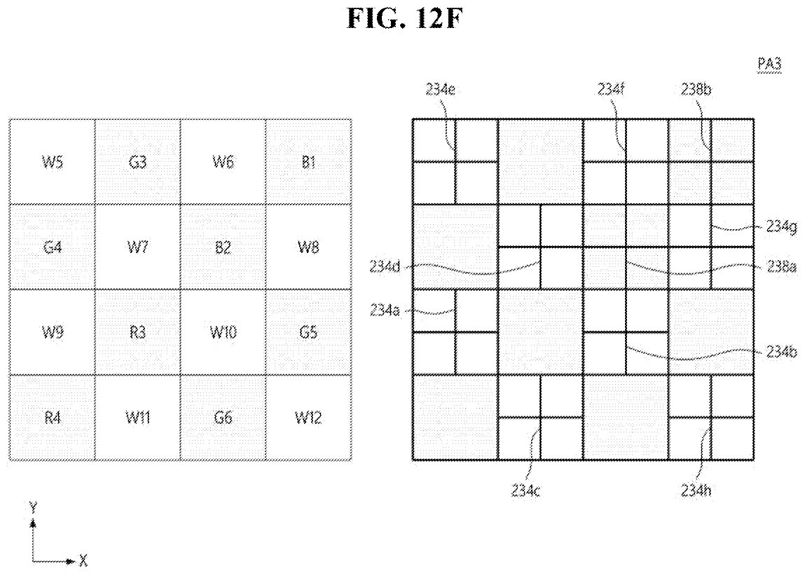

A pixel array PA3 according to some other embodiments will be described below referring to FIGS. 12A to 12F. FIGS. 12A to 12F are diagrams of a pixel array according to some embodiments. For convenience of explanation, repeated parts of contents explained using FIGS. 1 to 10 will be only briefly explained or omitted.

Referring to FIG. 12A, the second element separation films 234a to 234h may be placed in the fifth to twelfth white pixel regions W5 to W12. The second element separation films 234a to 234h may extend along the first direction X and the second direction Y. Further, each of the second element separation films 234a to 234h may partition each of the fifth to twelfth white pixel regions W5 to W12 into four sub-pixel regions.

The third element separation film 236a to 236d may be placed in the third to sixth green pixel regions G3 to G6. The third element separation films 236a to 236d may extend along the first direction X and the second direction Y. Further, each of the third element separation films 236a to 236d may partition each of the third to sixth green pixel regions G3 to G6 into four sub-pixel regions.

The fourth element separation films 238a and 238b may be placed in the first and second blue pixel regions B1 and B2. The fourth element separation films 238a and 238b may extend along the first direction X and the second direction Y. Also, each of the fourth element separation films 238a and 238b may partition each of the first and second blue pixel regions B1 and B2 into four sub-pixel regions.

The element separation film that partitions each pixel region into multiple sub-pixel regions may not be placed in the third and fourth red pixel regions R3 and R4. Since the element separation film is not placed in the third and fourth red pixel regions R3 and R4, the image quality of the image signal IS of the image sensor 100 can be further improved.

Referring to FIG. 12B, the second element separation films 234a to 234h may be placed in the fifth to twelfth white pixel regions W5 to W12. The third element separation film 236a to 236d may be placed in the third to sixth green pixel regions G3 to G6.

The element separation film that partitions each pixel region into multiple sub-pixel regions may not be placed in the third and fourth red pixel regions R3 and R4. In addition, the fourth element separation films 238a and 238b may not be placed in the first and second blue pixel regions B1 and B2. Since the fourth element separation films 238a and 238b are not placed in the first and second blue pixel regions B1 and B2, the image quality of the image signal IS of the image sensor 100 can be improved.

Referring to FIG. 12C, the second element separation films 234a to 234h may be placed in the fifth to twelfth white pixel regions W5 to W12.

The element separation film that partitions each pixel region into multiple sub-pixel regions may not be placed in the third and fourth red pixel regions R3 and R4. In addition, the fourth element separation films 238a and 238b may not be placed in the first and second blue pixel regions B1 and B2. Further, the third element separation films 236a to 236d may not be placed in the third to sixth green pixel regions G3 to G6. Since the third element separation films 236a to 236d are not placed in the third to sixth green pixel regions G3 to G6, the image quality of the image signal IS of the image sensor 100 can be improved.

Referring to FIG. 12D, the third element separation films 236a, 236b, 236c and 236d may be placed in the third to sixth green pixel regions G3 to G6.

The second element separation films 234a to 234h may not be placed in the fifth to twelfth white pixel regions W5 to W12. White color filters 231 and 233 of the fifth to twelfth white pixel regions W5 to W12 may transmit lights of all colors. That is, since the fifth to twelfth white pixel regions W12 to W5 may transmit light of long wavelength, a crosstalk of the adjacent pixel region PX may increase. Since the second element separation films 234a to 234h are not placed in the fifth to twelfth white pixel regions W5 to W12, the image quality of the image signal IS of the image sensor 100 can be improved.

Referring to FIG. 12E, the third element separation films 236a to 226d may be placed in the third to sixth green pixel regions G3 to G6. Further, the fourth element separation films 238a and 238b may be placed in the first and second blue pixel regions B1 and B2.

The second element separation films 234a to 234h may not be placed in the fifth to twelfth white pixel regions W5 to W12. In addition, the element separation film may not be placed in the third and fourth red pixel regions R3 and R4. Since the element separation film is not placed in the fifth to twelfth white pixel regions W5 to W12 and the third and fourth red pixel regions R3 and R4 that transmit light of long wavelength, the image quality of the image signal IS of the image sensor 100 can be improved.

Referring to FIG. 12F, the second element separation films 234a to 234h may be placed in the fifth to twelfth white pixel regions W5 to W12. Further, the fourth element separation films 238a and 238b may be placed in the first and second blue pixel regions B1 and B2. Since the element separation film is not placed in the third and fourth red pixel regions R3 and R4 that transmit light of long wavelength, the image quality of the image signal IS of the image sensor 100 can be improved.

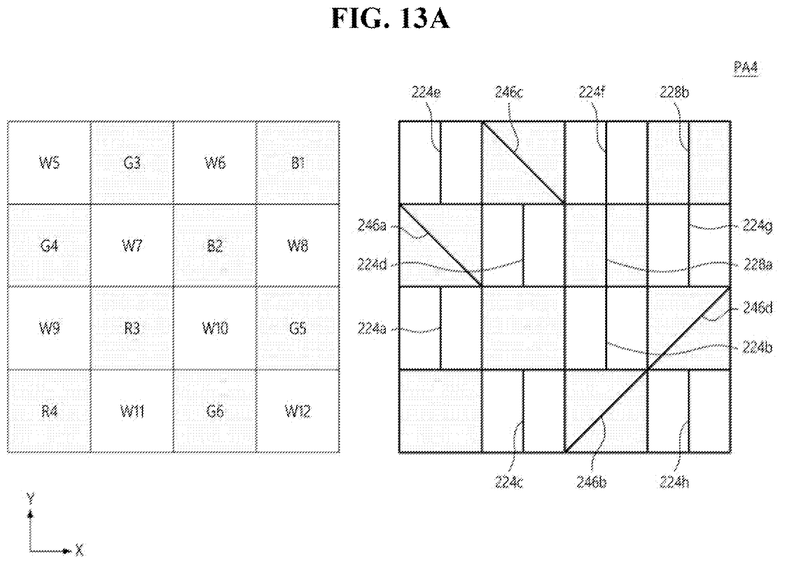

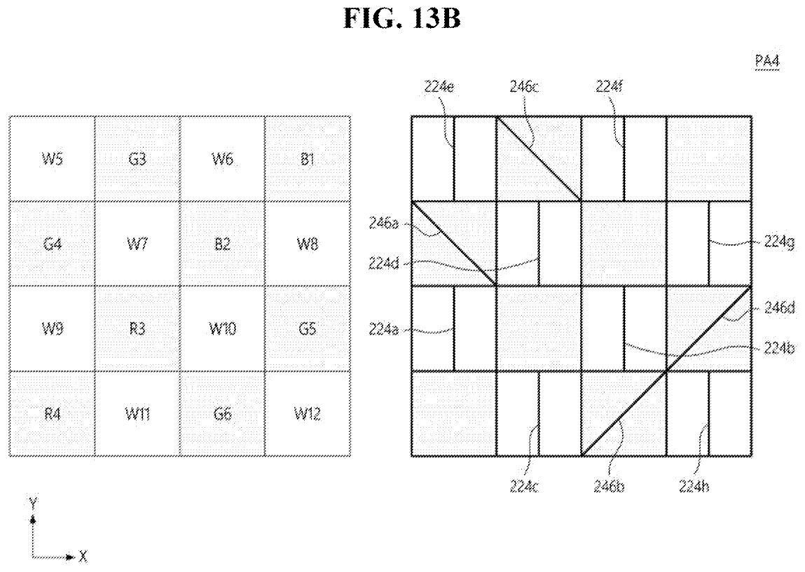

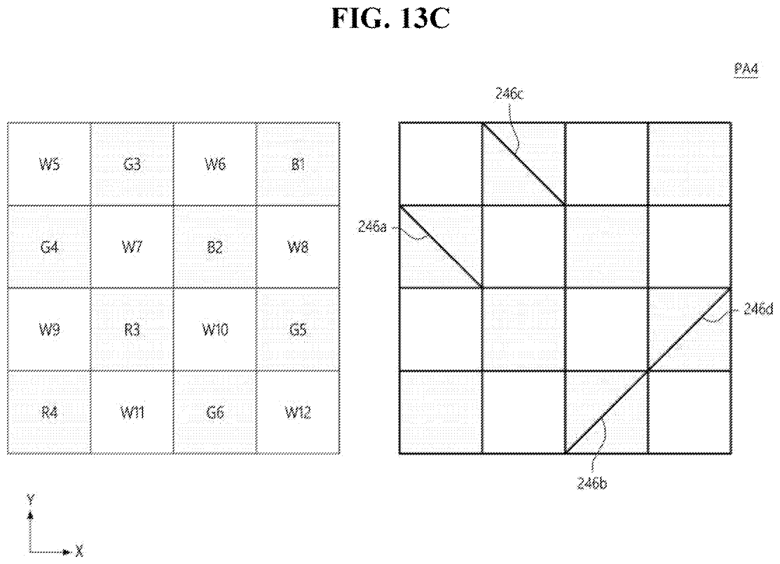

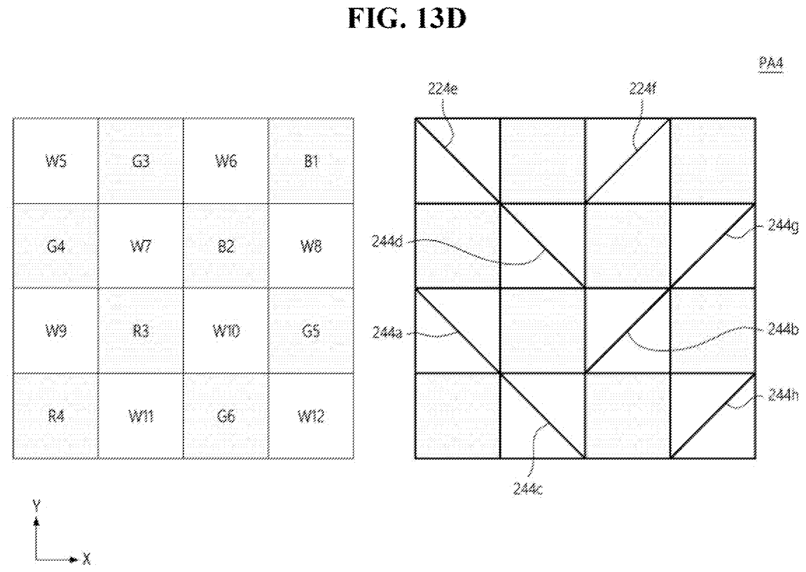

A pixel array PA4 according to some other embodiments will be described below referring to FIGS. 13A to 13D. FIGS. 13a to 13d are diagrams of a pixel array according to some embodiments. For convenience of explanation, repeated parts of contents explained using FIGS. 1 to 10 will be only briefly explained or omitted.

Referring to FIG. 13A, the second element separation films 224a to 224h may be placed in the fifth to twelfth white pixel regions W5 to W12. The second element separation films 224a to 224h may extend along the second direction Y. The fourth element separation films 228a and 228b may be placed in the first and second blue pixel regions B1 and B2. The fourth element separation films 228a and 228b may extend along the second direction Y.

The third element separation films 246a to 246d may be placed in the third to sixth green pixel regions G3 to G6. The third element separation films 246a to 246d may extend along a direction between the first direction X and the second direction Y. That is, the third element separation films 246a to 246d may extend in a diagonal direction. Further, each of the third element separation films 246a to 246d may partition each of the third to sixth green pixel regions G3 to G6 into two sub-pixel regions.

The element separation film that partitions each pixel region into multiple sub-pixel regions may not be placed in the third and fourth red pixel regions R3 and R4. Since the element separation film is not placed in the third and fourth red pixel regions R3 and R4, the image quality of the image signal IS of the image sensor 100 can be further improved.

Referring to FIG. 13B, as compared to FIG. 13A, the fourth element separation films 228a and 228b may not be placed in the first and second blue pixel regions B1 and B2. Since the fourth element separation films 228a and 228b are not placed in the first and second blue pixel regions B1 and B2, the image quality of the image signal IS of the image sensor 100 can be improved.

Referring to FIG. 13C, the third element separation films 246a, 246b, 246c and 246d may be placed in the third to sixth green pixel regions G3 to G6.

The second element separation films 224a to 224h may not be placed in the fifth to twelfth white pixel regions W5 to W12. White color filters 231 and 233 of the fifth to twelfth white pixel regions W5 to W12 may transmit lights of all colors. That is, since the fifth to twelfth white pixel regions W12 to W5 may transmit light of long wavelength, a crosstalk of the adjacent pixel region PX may increase. Since the second element separation films 224a to 224h are not placed in the fifth to twelfth white pixel regions W5 to W12, the image quality of the image signal IS of the image sensor 100 can be improved.

Referring to FIG. 13D, the second element separation films 244a to 244h may be placed in the fifth to twelfth white pixel regions W5 to W12. Each of the second element separation films 244a to 244h may extend along the direction between the first direction X and the second direction Y. That is, the second element separation films 244a to 244h may extend in the diagonal direction. Further, each of the second element separation films 244a to 244h may partition each of the fifth to twelfth white pixel regions W5 to W12 into two sub-pixel regions.

The element separation film that partitions each pixel region into multiple sub-pixel regions may not be placed in the third and fourth red pixel regions R3 and R4. In addition, the fourth element separation films 228a and 228b may not be placed in the first and second blue pixel regions B1 and B2. Further, the third element separation films 246a to 246d may not be placed in the third to sixth green pixel regions G3 to G6. As a result, the image quality of the image signal IS of the image sensor 100 can be improved.

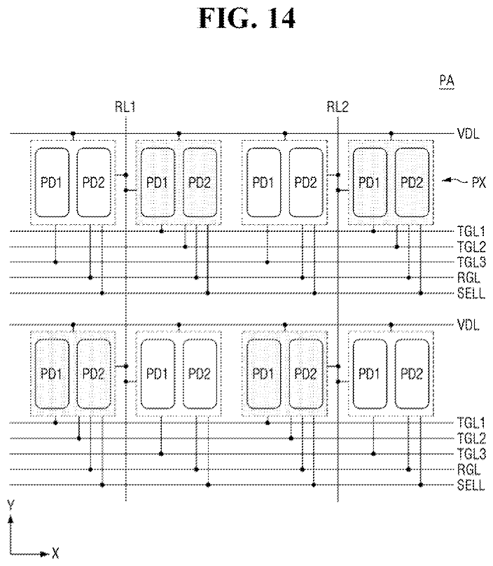

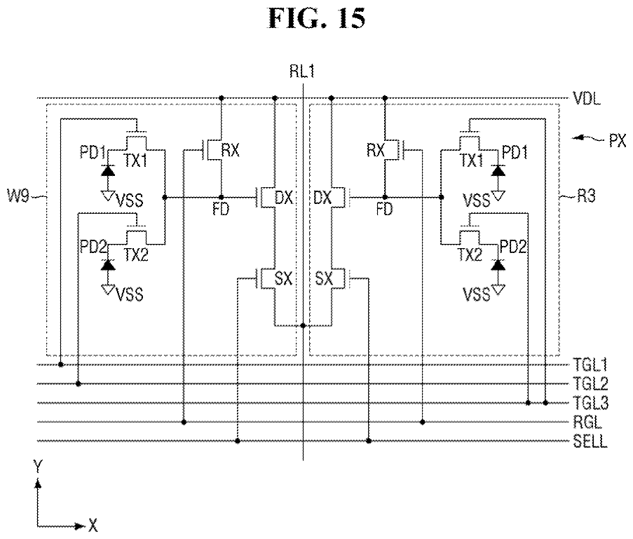

Hereinafter, the structure and operation of the pixel array PA and the pixel region PX according to some embodiments will be described referring to FIGS. 14 and 15.

FIG. 14 is a diagram of a plurality of pixels and signal lines of the image sensor 100, e.g., FIG. 14 illustrates a portion of the pixel array PA. It is noted FIG. 15 is an equivalent circuit diagram of two pixels of the image sensor 100.

Referring to FIG. 14, each pixel region PX in the image sensor 100 may include a plurality of first and second photoelectric conversion elements PD1 and PD2 that may perform the photoelectric conversion independently. The plurality of signal lines included in the pixel array PA may include a power supply voltage line VDL, a plurality of transfer signal lines TGL1, TGL2 and TGL3, a reset signal line RGL, and a selection signal line SELL for at least each row, and output signal lines RL1 and RL2 for at least each column. Two adjacent pixel regions PX that share one output signal, e.g., one of lines RL1 and RL2, may be connected to different transfer signal lines TGL1, TGL2 and TGL3.

The power supply voltage line VDL, the transfer signal lines TGL1, TGL2 and TGL3, the reset signal line RGL, and the selection signal line SELL may generally extend in the first direction X. The output signal lines RL1 and RL2 may extend in the second direction Y.

The power supply voltage line VDL transfers a constant power supply voltage, and the plurality of transfer signal lines TGL1, TGL2 and TGL3 placed in one row independently transfer first through third transfer signals, respectively, to transfer the charge generated by the photoelectric conversion elements PD1 and PD2 of the pixel region PX to the readout element. The reset signal line RGL may transfer a reset signal for resetting a pixel, and the selection signal line SELL may transfer a selection signal instructing the row selection. The first through third transfer signals, the reset signal, and the selection signal may be output from the row driver 130 described above. The row driver 130 may output the first through third transfer signals, the reset signal, and the selection signal for each row sequentially or non-sequentially.

In some embodiments, the ninth white pixel region W9 is connected to two transfer signal lines TGL1 and TGL2, and the third red pixel region R3 may be connected to one transfer signal line TGL3. The transfer signal line TGL3 may be a transfer signal line different from the two transfer signal lines TGL1 and TGL2. The pixel regions PX arranged in the same row may be connected to the same reset signal line RGL and the same selection signal line SELL.

Referring to FIG. 15, each of the pixel regions PX (e.g., dashed regions in FIG. 15) may include first and second photoelectric conversion elements PD1 and PD2, and a readout element that reads the photoelectric conversion signals of the first and second photoelectric conversion elements PD1 and PD2. The readout element may include first and second transfer transistors TX1 and TX2 connected between a floating diffusion node FD and the first and second photoelectric conversion elements PD1 and PD2, a reset transistor RX and a drive transistor DX connected between the floating diffusion node FD and the power supply voltage line VDL, and a selection transistor SX connected between the drive transistor DX and the output signal line RL1.

Each of the first and second photoelectric conversion elements PD1 and PD2 may be a photo diode with an anode connected to a common voltage VSS. A cathode of the photo diodes may be connected to the first and second transfer transistors TX1 and TX2, respectively. The charge generated when the first and second photoelectric conversion elements PD1 and PD2 receive light may be transmitted to the floating diffusion node FD through the first and second transfer transistors TX1 and TX2.

Gates of the first and second transfer transistors TX1 and TX2 may be connected to the transfer signal lines TGL1, TGL2 and TGL3 to receive application of the first through third transfer signals. For example, as described above, the gates of the first and second transfer transistors TX1 and TX2 of the ninth white pixel region W9 may be connected to different transfer signal lines TGL1 and TGL2. Further, gates of the first and second transfer transistors TX1 and TX2 of the third red pixel region R3 may be connected to the same transfer signal line TGL3. Therefore, the charges generated by each of the first and second photoelectric conversion elements PD1 and PD2 of the ninth white pixel region W9 may be transmitted to the floating diffusion node FD through the first and second transfer transistors TX1 and TX2 which are turned on at different times from each other. Also, the charges generated by each of the first and second photoelectric conversion elements PD1 and PD2 of the third red pixel region R3 may be transmitted together to the floating diffusion node FD through the first and second transfer transistors TX1 and TX2 which are turned on at the same time as each other. The floating diffusion node FD may store the transmitted charges in a cumulative manner, and the drive transistor DX may be controlled depending on the amount of charges stored in the floating diffusion node FD.

The gate of the reset transistor RX may be connected to the reset signal line RGL. The reset transistor RX may be controlled by the reset signal transferred by the reset signal line RGL to periodically reset the floating diffusion node FD to the power supply voltage.

The drive transistor DX may output a voltage that changes in response to the voltage of the floating diffusion node FD. The drive transistor DX may function as a source follower buffer amplifier in combination with a constant current source. The drive transistor DX may generate a source-drain current that is proportional to a dimension of the amount of charge applied to the gate.

A gate of the selection transistor SX is connected to the selection signal line SELL. The selection transistor SX which is turned on according to the activation of the selection signal transferred by the selection signal line SELL may output the current generated by the drive transistor DX to the output signal line RL1 as a pixel signal. The selection signal may be applied sequentially or non-sequentially on a line basis, as a signal which selects a row that outputs a pixel signal.

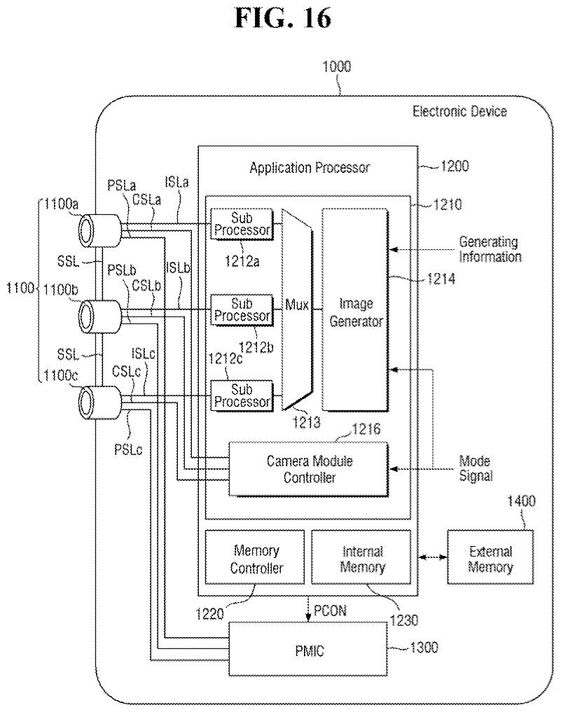

Hereinafter, an electronic device 1000 according to some other embodiments will be described with reference to FIG. 16. FIG. 16 is a block diagram of electronic device including a multi-camera module according to some embodiments.

Referring to FIG. 16, the electronic device 1000 may include a camera module group 1100, an application processor 1200, a power managements integrated circuit (PMIC) 1300, and an external memory 1400. For example, the electronic device may include mobile communication terminals, e.g., smartphones and tablet computers.

The camera module group 1100 may include first to third camera modules 1100a, 1100b and 1100c. In this embodiment, although the camera module group 1100 is exemplified as including three camera modules 1100a, 1100b and 1100c, the present disclosure is not limited thereto. In some embodiments, the camera module group 1100 may be implemented to include only two camera modules or to include n (n is a natural number equal to or greater than 4) camera modules.

At least two camera modules (e.g., 1100b and 1100c) among the first to third camera modules 1100a, 1100b and 1100c may have different field of views from each other. In this case, the optical lenses of at least two camera modules (e.g., 1100b and 1100c) among the first to third camera modules 1100a, 1100b and 1100c may be different from each other.

In some embodiments, viewing angles of each of the first to third camera modules 1100a, 1100b and 1100c may be different from each other. For example, the first camera module 1100a may be a tele camera, the second camera module 1100b may be a wide camera, and the third camera module 1100b may be an ultra-wide camera. In this case, the respective optical lenses of the plurality of camera modules 1100a, 1100b and 1100c may be different from each other.

In some embodiments, one camera module (e.g., 1100b) among the first to third camera modules 1100a, 1100b and 1100c may be a folded lens type camera module that includes a prism and an optical path folding element (OPFE), and the remaining camera modules (e.g., 1100a and 1100c) may be vertical type camera modules that do not include a prism and an OPFE. However, example embodiments are not limited thereto, and the camera modules may be implemented by other forms and other combinations.

In some embodiments, one camera module (e.g., 1100a) among the first to third camera modules 1100a, 1100b and 1100c may be a vertical type depth camera that extracts depth information using, e.g., IR (Infrared Ray). In this case, the application processor 1200 may merge image data provided from such a depth camera with image data provided from another camera module (e.g., 1100b or 1100c) to generate a three-dimensional (3D) depth image. Such a merging process will be described in detail in the description of the image processor 1210 to be described later.

The first to third camera modules 1100a, 1100b and 1100c adopted in this embodiment may be placed to be physically separated from each other. In detail, the plurality of camera modules 1100a, 1100b and 1100c do not dividedly use the sensing region of one image sensor, but an independent image sensor may be placed in each of the first to third camera modules 1100a, 1100b and 1100c. Some of the image sensors of the first to third camera modules 1100a, 1100b and 1100c may have a pixel array structure different from some others.

For example, one camera module of the first to third camera modules 1100a, 1100b and 1100c may include a first image sensor that has an RGB pixel array including red (R) pixels, green (G) pixels, and blue (B) pixels, and the remaining camera modules may include an RGBW pixel array including RGB pixels and white (W) pixels. For example, one camera module among the first to third camera modules 1100a, 1100b and 1100c may include the image sensor 100 described previously with reference to to FIGS. 1 to 15.

The application processor 1200 may include an image processor 1210, a memory controller 1220, and an internal memory 1230. The application processor 1200 may be implemented separately as semiconductor chips separate from the plurality of camera modules 1100a, 1100b and 1100c.

The image processor 1210 may include first to third sub-image processors 1212a, 1212b and 1212c, an image generator 1214, and a camera module controller 1216. The image processor 1210 may include a number of sub-image processors that corresponds to the number of first to third camera modules 1100a, 1100b and 1100c, i.e., first to third sub-image processors 1212a, 1212b and 1212c.

For example, the image data generated from the first camera module 1100a may be provided to the first sub-image processor 1212a through an image signal line ISLa, the image data generated from the second camera module 1100b may be provided to the second sub-image processor 1212b through an image signal line ISLb, and the image data generated from the third camera module 1100c may be provided to the third sub-image processor 1212c through an image signal line ISLc. Such an image data transfer may be performed, e.g., using a camera serial interface (CSI) based on a MIPI (Mobile Industry Processor Interface).

In another example, a plurality of sub-image processors corresponding to a plurality of camera modules may be implemented as a single sub-image processor. For example, although the first to third sub-image processors 1212a, 1212b and 1212c are shown as separate blocks in FIG. 16, they may be integrated and implemented as a single sub-image processor, and the image data provided from the first camera module 1100a and the third camera module 1100c may be selected by a multiplexer (MUX) 1213, which is a selection element, and then provided to the integrated sub-image processor. At this time, the second sub-image processor 1212b may not be integrated, and may receive the image data from the second camera module 1100b.

Further, in some embodiments, the image data generated from the first camera module 1100a may be provided to the first sub-image processor 1212a through the image signal line ISLa, the image data generated from the second camera module 1100b may be provided to the second sub-image processor 1212b through the image signal line ISLb, and the image data generated from the third camera module 1100c may be provided to the third sub-image processor 1212c through the image line ISLc. Further, although the image data processed by the second sub-image processor 1212b is directly provided to the image generator 1214, any one of the image data processed by the first sub-image processor 1212a and the image data processed by the third sub-image processor 1212c is selected through the multiplexer 1213, and then may be provided to the image generator 1214.

Each of the first to third sub-image processors 1212a, 1212b and 1212c may perform image processing, e.g., a bad pixel correction, a 3A adjustment (Auto-focus correction, Auto-white balance, Auto-exposure), a noise reduction, sharpening, a gamma control, and a remosaic on the image data provided from the first to third camera modules 1100a, 1100b and 1100c.

In some embodiments, the remosaic signal processing may be performed on the respective camera modules 1100a, 1100b and 1100c and then provided to the first to third sub-image processors 1212a, 1212b and 1212c. In this way, the image data processed by the first to third sub-image processors 1212a, 1212b and 1212c may be provided to the image generator 1214. For example, a first image signal processor may be included in the camera modules 1100a, 1100b and 1100c, and the first image signal processor may provide the processed image data to the first to third sub-image processors 1212a, 1212b and 1212c.

The image generator 1214 may generate a target image, using the image data provided from the respective first to third sub-image processors 1212a, 1212b and 1212c according to the image generating information or the mode signal. In detail, the image generator 1214 may merge at least some of the image data generated from the first to third sub-image processors 1212a, 1212b and 1212c to generate an output image, according to the image generating information or the mode signal. Further, the image generator 1214 may select any one of the image data generated from the first to third sub-image processors 1212a, 1212b and 1212c to generate the target image, according to the image generating information or the mode signal. Such a mode includes a plurality of various modes, and may be selected by a user or determined by an external environment.

The plurality of various modes may control the first to third camera modules 1100a, 1100b and 1100c through the camera module controller 1216 as well as the image generator 1214. The control signals provided from the camera module controller 1216 to the first to third camera modules 1100a, 1100b and 1100c may include information according to the selected mode.

The modes adopted in some embodiments include a plurality of still image modes and a plurality of moving image modes, and the camera module group 1100 of the electronic device 1000 according to the present embodiment may operate in another way depending on the signal of the selected mode among such modes.

In some embodiments, the plurality of modes may include first to third still image modes and first and second moving image modes. The plurality of modes may be described by the operation (particularly, output) of the second camera module 1100b which is a wide camera by the control signal. The second camera module 1100b may include an image sensor having an RGBW pixel array, unlike the image sensors of the first and third camera modules 1100a and 1100c.

On the other hand, the image generating information may include, e.g., a zoom signal (or a zoom factor). The zoom signal may be, e.g., signal selected from the user.

If the image generating information is a zoom signal (or zoom factor), and the first to third camera modules 1100a, 1100b and 1100c have different fields of view (or viewing angles), the image generator 1214 may perform different operations from each other, depending on the type of zoom signal. For example, when the zoom signal is a first signal, the output image may be generated, using the image data output from the first sub-image processor 1212a among the image data output from the first sub-image processor 1212a and the image data output from the third sub-image processor 1212c, and the image data output from the second sub-image processor 1212b.

When the zoom signal is a second signal different from the first signal, the image generator 1214 may generate the output image, using the image data output from the third sub-image processor 1212c among the image data output from the first sub-image processor 1212a and the image data output from the third sub-image processor 1212c, and the image data output from the second sub-image processor 1212b.

When the zoom signal is still another third signal, the image generator 1214 may select any one of the image data output from the respective first to third sub-image processors 1212a, 1212b and 1212c to generate the output image, without merging the image data. In addition to the above-mentioned generation process, the method of processing the image data in another generation process according to another zoom signal may be variously modified and implemented.

The camera control signal according to the mode selection may be provided to each of the camera modules 1100a, 1100b and 1100c by the camera module controller 1216. The control signals generated from the camera module controller 1216 may be provided to the corresponding first to third camera modules 1100a, 1100b and 1100c through control signal lines CSLa, CSLb, and CSLc separated from each other.

On the other hand, any one of the first to third camera modules 1100a, 1100b and 1100c is designated as a master camera (for example, 1100b) according to the image generating information including the zoom signal and the mode, and the remaining camera modules (e.g., 1100a and 1100c) may be specified as slave cameras. Such information is included in the control signal, and may be provided to the corresponding first to third camera modules 1100a, 1100b and 1100c through the control signal lines CSLa, CSLb, and CSLc separated from each other.

The PMIC 1300 may supply power, e.g., a power supply voltage, to each of the first to third camera modules 1100a, 1100b and 1100c. For example, the PMIC 1300 may supply a first power to the first camera module 1100a through a power signal line PSLa, supply a second power to the second camera module 1100b through a power signal line PSLb, supply a third power to the camera module 1100c through a power signal line PSLc, under the control of the application processor 1200.

The PMIC 1300 may generate power corresponding to each of the first to third camera modules 1100a, 1100b and 1100c and adjust the power level, in response to a power control signal PCON from the application processor 1200. The power control signal PCON may include a power adjustment signal for each operating mode of a plurality of camera modules 1100a, 1100b and 1100c. For example, the operating mode may include a low power mode, and at this time, the power control signal PCON may include information about the camera module operating in the low power mode and the set power level. The levels of powers provided to each of the first to third camera modules 1100a, 1100b and 1100c may be the same as or different from each other. Also, the levels of powers may be changed dynamically.

By way of summation and review, aspects of the present disclosure provide an image sensor that prevents crosstalk between pixels to improve an image quality, and an image sensing system that includes the same. That is, according to example embodiments, an ,e.g., RGBW, image sensor may not include an element separation film or a separation trench between photo diodes within a same red pixel, thereby reducing crosstalk of the image sensor.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. An image sensor, comprising:
a substrate;
a first element separation film inside the substrate, the first element separation film having a mesh shape;
pixel regions on the substrate defined by the first element separation film, the pixel regions including at least a first pixel region and a second pixel region; and
a second element separation film inside the substrate, the second element separation film partitioning the first pixel region into sub-pixel regions, and the second element separation film not being in the second pixel region,
wherein the first pixel region includes:
first photoelectric conversion elements, and
a first color filter on the first photoelectric conversion elements, the first color filter being one of a white color filter, a green color filter, and a blue color filter, and
wherein the second pixel region includes:
second photoelectric conversion elements, and
a second color filter on the second photoelectric conversion elements, the second color filter being one of a red color filter and the white color filter, and the second color filter being different from the first color filter.

2. The image sensor as claimed in claim 1, wherein the second color filter is the red color filter, and the first color filter is the white color filter.

3. The image sensor as claimed in claim 1, wherein:
the pixel regions further include a third pixel region defined by the first element separation film, the third pixel region including third photoelectric conversion elements, and a third color filter on the third photoelectric conversion elements,
the third pixel region is in contact with the second pixel region, and
the third pixel region is not in contact with the first pixel region.

4. The image sensor as claimed in claim 3, wherein:
the third color filter is one of the white color filter, the green color filter, and the blue color filter, and
the image sensor further comprises a third element separation film inside the substrate, the third element separation film partitioning the third pixel region into sub-pixel regions.

5. The image sensor as claimed in claim 3, wherein:
the third color filter is one of the red color filter and the white color filter, and
the second element separation film is not placed in the third pixel region.

6. The image sensor as claimed in claim 1, wherein a length of a wavelength of light transmitted by the second color filter is larger than a length of a wavelength of light transmitted by the first color filter.

7. The image sensor as claimed in claim 1, wherein the first pixel region and the second pixel region are adjacent to each other, the first element separation film being a boundary between the first pixel region and the second pixel region.

8. The image sensor as claimed in claim 7, wherein the second element separation film is parallel to the first element separation film in a region between the first pixel region and the second pixel region.

9. The image sensor as claimed in claim 8, wherein the second element separation film partitions the first pixel region into two sub-pixel regions.

10. The image sensor as claimed in claim 1, wherein the substrate includes a first surface and a second surface opposite to the first surface, the first and second color filters being on the second surface, and the first element separation film penetrating the substrate and is exposed to each of the first surface and the second surface.

11. The image sensor as claimed in claim 10, wherein the second element separation film is exposed to the second surface and is not exposed to the first surface.

12. The image sensor as claimed in claim 10, wherein the second element separation film penetrates the substrate and is exposed to the first surface and the second surface, an area of the second element separation film exposed to the first surface being greater than an area of the first element separation film exposed to the second surface.

13. The image sensor as claimed in claim 1, wherein the first element separation film between the first pixel region and the second pixel region extends in a first direction, and the second element separation film includes a first sub-element separation film that extends in the first direction.

14. The image sensor as claimed in claim 13, wherein the second element separation film includes a second sub-element separation film extending in a second direction intersecting the first direction.

15. An image sensor, comprising:
a substrate including a first pixel region and a second pixel region;
first photoelectric conversion elements inside the substrate in the first pixel region;
second photoelectric conversion elements inside the substrate in the second pixel region;
a boundary separation film at a boundary between the first pixel region and the second pixel region;
a pattern film inside a portion of the substrate of the first pixel region, the pattern film not being in the second pixel region;
a first color filter on the first pixel region of the substrate, the first color filter being one of a white color filter, a green color filter, and a blue color filter; and
a second color filter on the second pixel region of the substrate, the second color filter being a red color filter.

16. The image sensor as claimed in claim 15, wherein the first color filter is the white color filter.

17. The image sensor as claimed in claim 15, wherein the boundary separation film extends in a first direction, and the pattern film includes a first sub-pattern film that extend in the first direction.

18. The image sensor as claimed in claim 17, wherein the pattern film includes a second sub-pattern film that extend in a second direction intersecting the first direction.

19. The image sensor as claimed in claim 15, wherein the first photoelectric conversion elements include two first photoelectric conversion elements, and the pattern film inside the substrate being between the two first photoelectric conversion elements.

20. An image sensing system, comprising:
an image sensor configured to output an image signal; and
an image signal processor connected to the image sensor, the image signal processor being configured to receive and process the image signal,
wherein the image sensor includes
a substrate,
a first element separation film inside the substrate and having a mesh shape,
pixel regions defined by the first element separation film, the pixel regions including at least a first pixel region, a second pixel region, and a third pixel region,
a second element separation film inside the substrate, the second element separation film partitioning the first pixel region into sub-pixel regions, and the second element separation film not being in the second pixel region, and
a third element separation film inside the substrate, the third element separation film partitioning the third pixel region into sub-pixel regions, and the third element separation film not being in the second pixel region,
wherein:
the second pixel region is adjacent to the first pixel region with the first element separation film as a boundary therebetween, and the second pixel region is adjacent to the third pixel region with the first element separation film as a boundary therebetween,
the first pixel region includes first photoelectric conversion elements, and a first color filter on the first photoelectric conversion elements,
the second pixel region includes second photoelectric conversion elements, and a second color filter on the second photoelectric conversion elements,
the third pixel region includes third photoelectric conversion elements, and a third color filter on the third photoelectric conversion elements, and
the second color filter is different from the first and third color filters, the first color filter being one of a white color filter, a green color filter, and a blue color filter, the second color filter being one of a red color filter and the white color filter, and the third color filter being one of the white color filter, the green color filter, and the blue color filter.
